(19) United States
(12) Patent Application Publication
(10) Pub. No.: US 2008/0081443 A1
(43) Pub. Date: Apr. 3, 2008

(54) Method for fabricating semiconductor

(75) Inventor: Toshio Nagata, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/892,855

(22) Filed: Aug. 28, 2007

(30) Foreign Application Priority Data
Sep. 28, 2006 (JP) 2006-263822

(51) Int. Cl. H01L 21/20

(52) U.S. Cl. 438/481; 257/E21.121

(57) ABSTRACT

According to the present invention, a method for fabricating a semiconductor device using a Silicon-On-Sapphire (SOS) wafer comprises a process for preparing a sapphire substrate, a process for forming a silicon (Si) layer on the sapphire substrate, a process for implanting silicon ions in the silicon layer, and a process for inducing epitaxial regrowth in the silicon layer after the silicon ion implantation. The silicon ion implantation process induces the number of interstitial Si having crystalline defects in the proximity of the surface of said silicon layer to be reduced below 6.5E2/cm3; and induces an ion implantation amount per unit area of said silicon ions in the proximity of an interface between said sapphire substrate and said silicon layer to be increased to 3.0E19 ions/cm3 or more.

### CROSS REFERENCE TO RELATED APPLICATION

This application claims the priority of Application No. 2006-263822, filed Sep. 28, 2006 in Japan, the subject matter of which is incorporated herein by reference.

### TECHNICAL FIELD OF THE INVENTION

The present invention relates to a method for fabricating a semiconductor device using a wafer of a Silicon-On-Sapphire (SOS) structure, and, more particularly, to improved epitaxial re-growth technology for a silicon layer formed on a sapphire substrate.

### BACKGROUND OF THE INVENTION

As described in Japanese Patent Publication No. 3492372, Silicon-On-Sapphire (SOS) wafers have been in use in high-performance MOSFET microelectronics, mainly in use for an application requiring radiation hardness. A silicon film is normally formed by epitaxial growth on a sapphire substrate. Preferably, a silicon film is thinner than a source-drain distance (channel length) and an insulating substrate is thick enough to suppress significant electrostatic coupling to a back surface or a package surface. A silicon film may have a crystalline defect due to the crystal and thermal expansion incoherency between silicon and sapphire. The quality of a silicon film can be improved by increasing the thickness of silicon, and a common SOS wafer is formed using a silicon layer having a thickness ranging from 400 to 800 nanometers. This film thickness is sufficient to support a transistor having a channel length of approx. 1 micron max.

The use of an SOS wafer offers the advantages of substantially reducing parasitic capacitance between a charged active region and a substrate and of effectively removing leak current flowing between proximate elements.

Preferably, a silicon-On-Sapphire wafer is thick enough to support an active element and employs a completely single crystalline defect-free silicon layer. A silicon layer is adjacent to a sapphire substrate and the interface between silicon and sapphire has a minimum crystal lattice discontinuity portion.

It is known that major crystalline defects are removable by solid phase epitaxial (SPE) regrowth. The SPE process is a low temperature sub process to improve the degree of crystallization in the silicon epitaxial layer of an SOS composite substrate. This process can form a substantially non-crystalline silicon layer in the proximity of a silicon/sapphire interface, while leaving a substantially crystalline layer in the surface proximity of the original epitaxial layer. To do this, the PSE process performs high-energy implantation of ion seeds of silicon or the like into a silicon epitaxial layer. It then performs a single-step low-temperature annealing of the composite substrate to convert non-crystalline silicon layer into crystalline silicon. Since the remaining crystalline surface portion of the silicon epitaxial layer serves as a seed crystal for crystal nucleation during the regrowth, the regrown portion of the silicon epitaxial layer shares the common crystal orientation with the aforementioned crystalline surface portion, thereby leading to an absence of crystalline defects.

The invention described in the aforementioned Japanese Patent Publication No. 3492372 conducts silicon ion implantation (Si implantation) into a silicon layer under the conditions of a dosage of 6E14 ions/cm² and implantation energy of 185 KeV. Execution of this Si implantation can reduce crystalline defects by the magnitude of 2 orders. Unfortunately, crystalline defects in a silicon epitaxial layer adversely affect device characteristics and hence deteriorate device performance (speed). Therefore reduction of crystalline defects in a silicon epitaxial layer is essential to improve device characteristics.

Unfortunately, ion implantation according to the conventional method has failed to sufficiently reduce crystalline defects. Defects, particularly crystalline defects, in a SOS wafer result in a deterioration of the characteristics of a semiconductor device that will be fabricated using such wafer.

### OBJECTS OF THE INVENTION

A primary object of the present invention is to provide a method for fabricating a semiconductor device to contribute to an improvement in the characteristics of a semiconductor device, which is to be fabricated according to such method, by improving the quality of a silicon epitaxial layer formed on a sapphire substrate.

Additional objects, advantages and novel features of the present invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### SUMMARY OF THE INVENTION

According to a first aspect of the present invention, a method for fabricating a semiconductor device using an SOS (Silicon-On-Sapphire) wafer comprises the steps of: preparing a sapphire substrate; forming a silicon (Si) layer on the sapphire substrate; implanting silicon ions into the silicon layer; and epitaxially regrowing the silicon layer upon completion of the silicon ion implantation. The ion implantation process induces the number of interstitial Si in the proximity of the surface of the silicon layer having crystalline defects to be reduced below 6.5E21/cm3; and induces an ion dose per unit area in the proximity of the interface between the sapphire substrate and the silicon layer to be increased to 3.0E19 ions/cm3 or more.

According to a second aspect of the present invention, a method for fabricating a semiconductor device using an SOS (Silicon-On-Sapphire) wafer comprises the steps of: preparing a sapphire substrate; forming a silicon (Si) layer on the sapphire substrate; implanting silicon ions into the silicon layer under the condition of a dosage of 8E14 ions/cm2 to 8.5E14 ions/cm2; and epitaxially growing the silicon layer upon completion of the silicon ion implantation.

According to a third aspect of the present invention, a method for fabricating a semiconductor device using an SOS (Silicon-On-Sapphire) wafer comprises the steps of: preparing a sapphire substrate; forming a silicon (Si) layer on the sapphire substrate; implanting silicon ions into the silicon layer under the condition of ion implantation energy ranging from 140 KeV to 160 KeV; and epitaxially regrowing the silicon layer upon completion of the silicon ion implantation.

In each aspect of the present invention as described above, the region signified by the recital “around the surface” may be set to a range at a depth of 200 Å from the surface of a silicon layer. Since crystalline defects in a silicon layer exist most in the range of 600 Å from the interface with the sapphire substrate, it is essential to induce the interface region to become amorphous by implanting silicon into the relevant region.

In a silicon ion implantation, by reducing the number of interstitial Si in the proximity of the surface of a silicon layer having crystalline defects below 6.5E21/cm3 and increasing an ion dose per unit area into the proximity of the interface between the sapphire substrate and the silicon layer to 3.0E19 ions/cm3 or more, crystalline defects in an epitaxially grown silicon layer can be reduced, thereby improving device characteristics.

Silicon ion implantation into a silicon layer under the condition of a dosage of 8E14 ions/cm2 to 8.5E14 ions/cm2 can attain an ion dose per unit area into the proximity of the interface between the sapphire substrate and the silicon layer of 3.0E19 ions/cm3 or more. This can induce the silicon layer to become amorphous sufficiently in the proximity of the interface with the sapphire substrate and suppress the silicon layer from becoming amorphous in the proximity of the surface of the silicon layer as well. At this time, the number of interstitial Si in the proximity of a silicon layer having crystalline defects can be suppressed below 6.5E21/cm3, thereby preventing device characteristics from deteriorating.

Employing ion implantation energy of 140 KeV to 160 KeV in the execution of silicon ion implantation into a silicon layer can attain a silicon ion dose per unit area in the proximity of the interface between a sapphire substrate and a silicon layer of 3.0E19/cm3 or more. This can induce the silicon layer to become amorphous sufficiently in the proximity of the interface with the sapphire substrate, and suppresses the silicon layer from becoming amorphous in the proximity of the surface of the silicon layer as well. At this time, the number of interstitial Si in the proximity of a silicon layer having crystalline defects can be suppressed at a low level (below 6.5E21/cm3), thereby preventing device characteristics from deteriorating.

### BRIEF DESCRIPTION OF THE DRAWINGS

FIGS. 1A to 1C are cross-sectional views an SOS wafer schematically showing fabrication steps of the SOS wafer according to the present invention.

FIG. 2 is a graph showing a becoming-amorphous rate of a silicon layer, wherein ion implantation into the silicon layer was executed under conventional conditions according to a comparative example (a dosage: 4E14 ions/cm2).

FIG. 3 is a graph showing a becoming-amorphous rate of a silicon layer, wherein ion implantation into the silicon layer was executed under conventional conditions according to a comparative example (a dosage: 6E14 ions/cm2).

FIG. 4 is a graph showing a becoming-amorphous rate of a silicon layer, wherein ion implantation into the silicon layer was executed under the conditions pertinent to an embodiment according to the present invention (a dosage: 8E14 ions/cm2).

FIG. 5 is a graph showing a becoming-amorphous rate of a silicon layer, wherein ion implantation into the silicon layer was executed under conventional conditions according to a comparative example (a dosage: 8.8E14 ions/cm2).

FIG. 6 is a graph showing characteristic of each semiconductor device fabricated using a wafer comprising a silicon layer subjected to ion implantation, wherein ion implantation was executed under conventional conditions according to a comparative example (a dosage: other than 8E14 ions/cm2) and under conditions according to an embodiment (a dosage: 8E14 ions/cm2).

FIG. 7 is a graph showing the ion amount per unit area implanted into a silicon layer (amount of ion implantation in ions/cm3), wherein the silicon layer was subjected to ion implantation under conventional conditions according to a comparative example (a dosage: 6E14 ions/cm2) and under conditions according to an embodiment (a dosage: 8E14 ions/cm2).

FIG. 8 is a graph showing the amount of defective interstitial silicon existing in the proximity of the surface of a silicon layer, wherein the silicon layer was subjected to ion implantation under conventional conditions according to a comparative example (a dosage: 6E14 ions/cm2) and under conditions according to an embodiment (a dosage: 8E14 ions/cm2).

FIG. 9 is a graph showing a becoming-amorphous rate of a silicon layer, wherein ion implantation into the silicon layer was executed under conventional conditions according to a comparative example (implantation energy: 185 KeV).

FIG. 10 is a graph showing a becoming-amorphous rate of a silicon layer, wherein ion implantation into the silicon layer was executed under conventional conditions according to a comparative example (implantation energy: 170 KeV).

FIG. 11 is a graph showing a becoming-amorphous rate of a silicon layer, wherein ion implantation into the silicon layer was executed under the conditions according to an embodiment (implantation energy: 160 KeV).

FIG. 12 is a graph showing a becoming-amorphous rate of a silicon layer, wherein ion implantation into the silicon layer was executed under the conditions according to an embodiment (implantation energy: 150 KeV).

FIG. 13 is a graph showing a becoming-amorphous rate of a silicon layer, wherein ion implantation into the silicon layer was executed under the conditions according to an embodiment (implantation energy: 140 KeV).

FIG. 14 is a graph showing characteristic of each semiconductor device fabricated using a wafer comprising a silicon layer subjected to ion implantation, wherein ion implantation was executed under conventional conditions according to a comparative example (implantation energy: 185 KeV) and under conditions according to an embodiment (implantation energy: 150 KeV).

FIG. 15 is a graph showing the ion amount per unit area (ion implantation amount ions/cm3) implanted into a silicon layer, wherein the silicon layer was subjected to ion implantation under conventional conditions according to a comparative example (implantation energy: 185 KeV) and under conditions according to an embodiment (implantation energy: 150 KeV).

FIG. 16 is a graph showing the amount of defective interstitial silicon existing in the proximity of the surface of a silicon layer, wherein the silicon layer was subjected to ion implantation under conventional conditions according to a comparative example (implantation energy: 185 KeV) and under conditions according to an embodiment (implantation energy: 150 KeV).

10: Sapphire substrate
12: silicon layer
12a: Amorphous silicon layer
12b: Epitaxially regrown silicon layer

### DETAILED DISCLOSURE OF THE INVENTION

In the following detailed description of the preferred embodiments, reference is made to the accompanying drawings which form a part hereof, and in which is shown by way of illustration specific preferred embodiments in which the inventions may be practiced. These preferred embodiments are described in sufficient detail to enable those skilled in the art to practice the invention, and it is to be understood that other preferred embodiments may be utilized and that logical, mechanical and electrical changes may be made without departing from the spirit and scope of the present inventions. The following detailed description is, therefore, not to be taken in a limiting sense, and scope of the present inventions is defined only by the appended claims.

### First Embodiment

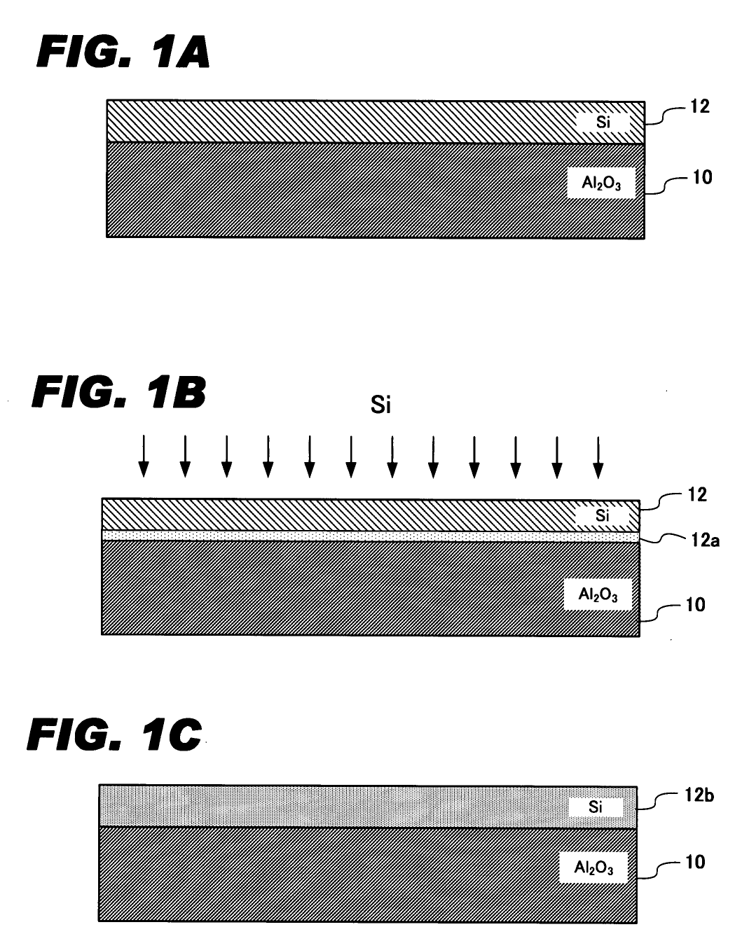

FIGS. 1A to 1C are cross-sectional views of an SOS wafer schematically showing a part of fabrication steps of the SOS wafer according to the present invention.

As shown in FIG. 1A, a silicon layer 12 having a thickness of approx. 2800 Å on a sapphire substrate. Next as shown in FIG. 1B, silicon ions are implanted into the silicon layer 12 to induce an amorphous region 12a to be formed in the proximity of the interface with the sapphire substrate 10. Then as shown in FIG. 1C, the silicon layer is epitaxially regrown (12b). The present invention applies to the process shown in FIG. 1B and provides optimized conditions for silicon ion implantation so as to suppress defects in the epitaxially grown silicon layer 12b.

The first embodiment of the present invention provides an optimized dosage (density: the number of ions per unit area) for Si implantation into the silicon layer 12. In practice in this embodiment, the conditions of a dosage of 8E14/cm2 (±10%) and implantation energy of 185 Kev are employed for silicon ion implantation, instead of the conventional conditions of a dosage of 6E14/cm2 and implantation energy of 185 Kev.

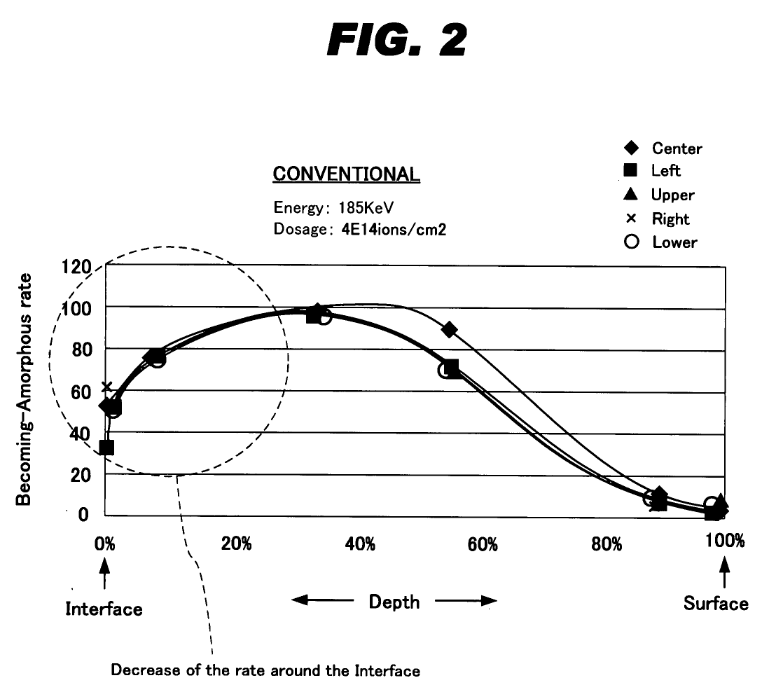

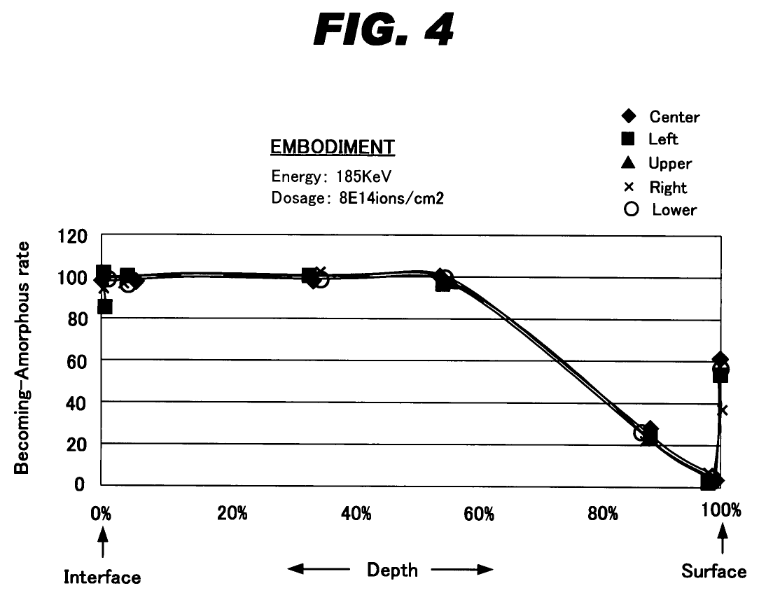

FIGS. 2 to 5 show the becoming-amorphous rate, that is, data of becoming-amorphous profile dependent upon a dosage, of a silicon layer 12 (12b), wherein ion implantation into the silicon layer was executed under various conditions. The examples shown in FIGS. 2, 3 and 5 employed dosages of 4E14 ions/cm2, 6E14 ions/cm2 and 8.8E14 ions/cm2, respectively, for the conditions pertinent to comparative examples (conventional examples). The example shown in FIG. 4, to the contrary, employed a dosage of 8E14 ions/cm2 for the condition pertinent to this embodiment. It is to be noted that entire data acquisition employed the common implantation energy of 185 KeV.

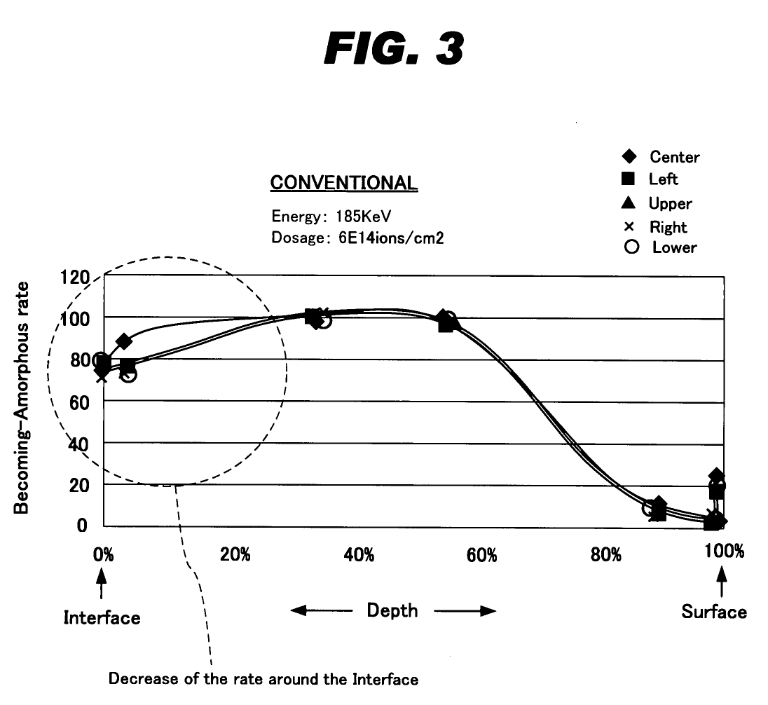

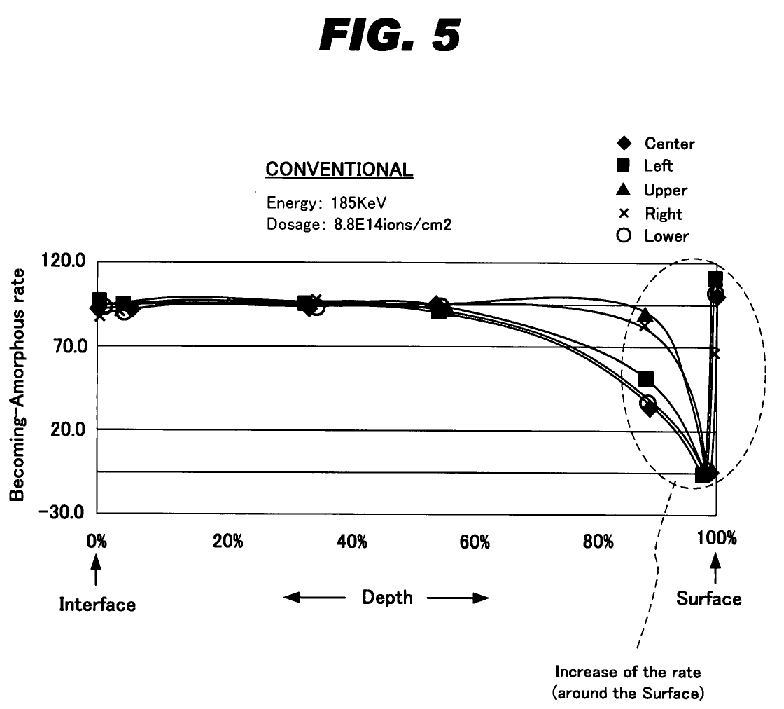

Obviously as seen from these figures, becoming-amorphous rates dropped in the proximity of the interface with a sapphire substrate 10 under the conventional conditions of dosages of 4E14/cm2 (FIG. 2) and 6E14/cm2 (FIG. 3). On the other hand, employing a dosage of 8.8E14/cm2 or more (FIG. 5) boosted the becoming-amorphous rates on the surface side of a silicon layer 12, thereby incurring a loss of crystallization on the surface side. To the contrary, the condition according to the present embodiment of a dosage of 8E14/cm2 (FIG. 4) provided a becoming-amorphous rate of almost 100% in the proximity of the interface with the sapphire substrate.

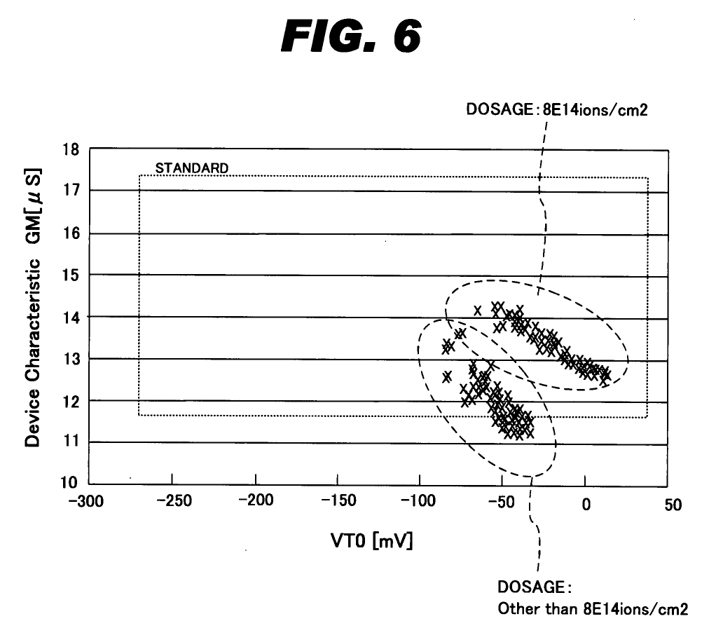

FIG. 6 is a graph showing characteristic of each semiconductor device fabricated using a wafer comprising a silicon layer subjected to ion implantation, wherein ion implantation was executed under conditions according to a comparative example (a dosage: 8E14 ions/cm2) and under conditions pertinent to an embodiment according to the present invention (a dosage: 8E14 ions/cm2). Employing the conditions of a comparative example (a dosage of other than 8E14 ions/cm2) suffered from deterioration of a resulted transistor characteristic (Gm). Considering the facts as shown above, it is supposed that retaining the profile of becoming-amorphous rate is essential in order to retain a good transistor characteristic.

Since defects tended to be incurred in a range of within 600 Å from the interface with the sapphire substrate in the silicon layer, more silicon ions should be implanted into this region.

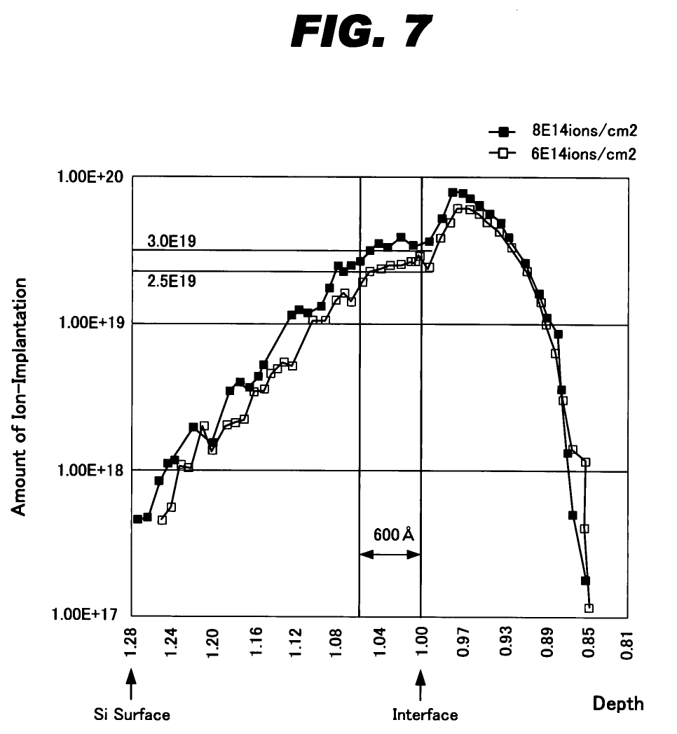

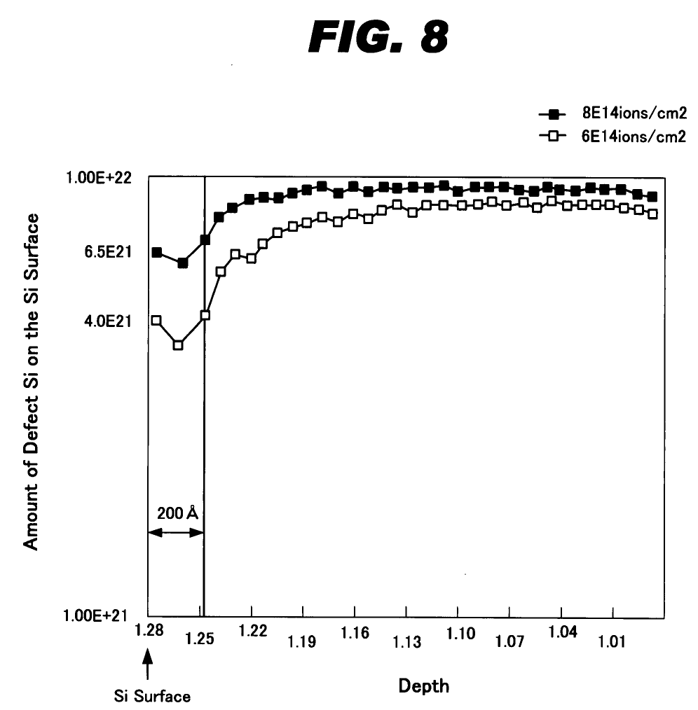

FIG. 7 is a graph showing the ion amount per unit area implanted into a silicon layer (amount of ion implantation in ions/cm3), wherein the silicon layer was subjected to ion implantation under conditions according to a comparative example (a dosage: 6E14 ions/cm2) and under conditions pertinent to an embodiment according to the present invention (a dosage: 8E14 ions/cm2). FIG. 8 is a graph showing the amount of defective interstitial silicon existing in the proximity of the surface of a silicon layer, wherein the silicon layer was subjected to ion implantation under conventional conditions according to a comparative example (a dosage: 6E14 ions/cm2) and under conditions pertinent to an embodiment according to the present invention (a dosage: 8E14 ions/cm2).

Under the conditions according to a comparative example (a dosage: 6E14 ions/cm2), the amount of ion implantation per unit area in the silicon layer in the range of within 600 Å from the interface with the sapphire substrate 10 were 2.5E19/cm3. To the contrary, under the conditions according to this embodiment (a dosage: 8E14 ions/cm2), the amount of ion implantation per unit area in the silicon layer in the range of within 600 Å from the interface with the sapphire substrate 10 were 3.0E19/cm3 or more. Thus implantation of more ions into the silicon layer can reduce the defects in the silicon layer.

Increasing of amount of ion implantation, however, leads to an increase of interstitial Si existing in the surface of a silicon layer, which may incur crystallization in the surface proximity (200 Å from the surface) to be deteriorated. However, as long as the conditions according to this embodiment (a dosage of 8E14/cm2) is employed as shown in FIG. 8, the transistor characteristic did not exhibit deterioration notwithstanding the presence of an amount of interstitial Si of 6.5E21/cm3 (FIG. 6). Therefore, the optimized dosage presented in this embodiment may be acceptable. The prescription of a range of within 200 Å assumes the fact that the silicon layer within this range, serving as seed crystal, contributes to epitaxial regrowth.

### Second Embodiment

The second embodiment of the present invention provides optimized implantation energy for Si implantation into the silicon layer 12. In practice in this embodiment, the conditions of a dosage of 6E14/cm2 (±10%) and implantation energy of 160 KeV to 140 Kev are employed for silicon ion implantation, instead of the conventional conditions of a dosage of 6E14/cm2 and implantation energy of 185 Kev.

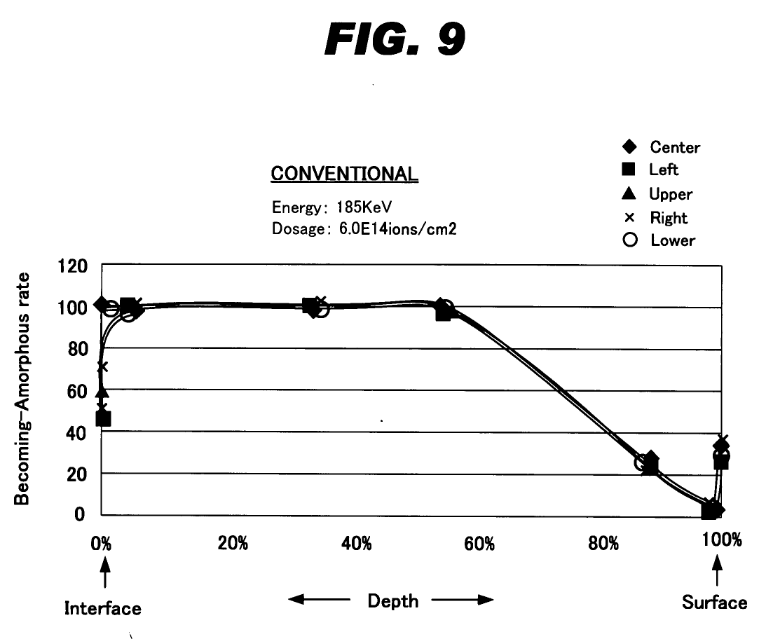

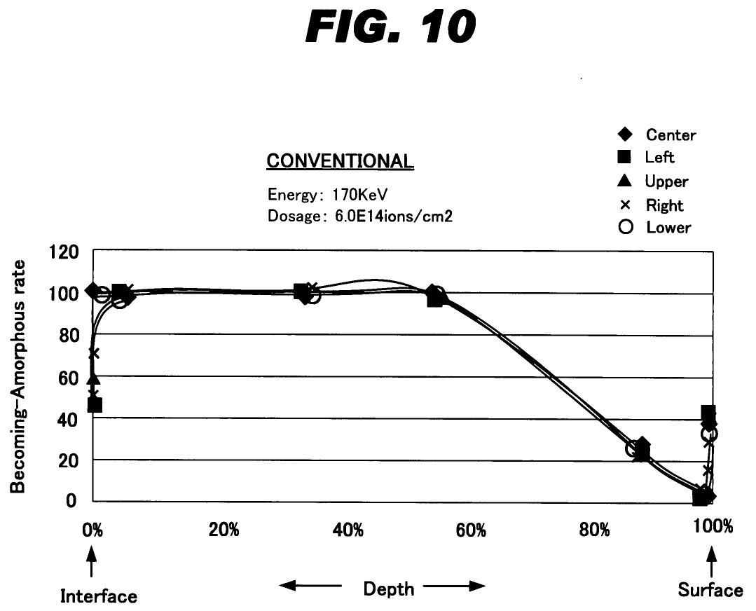

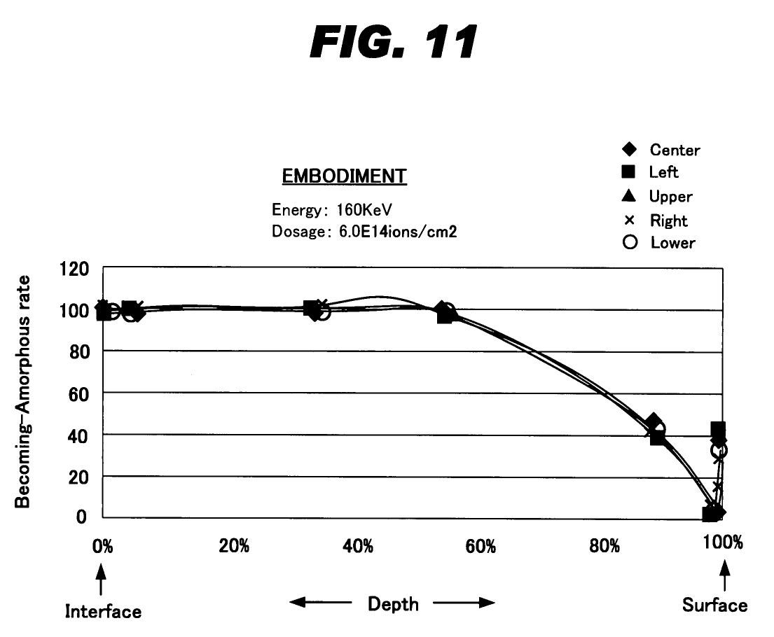

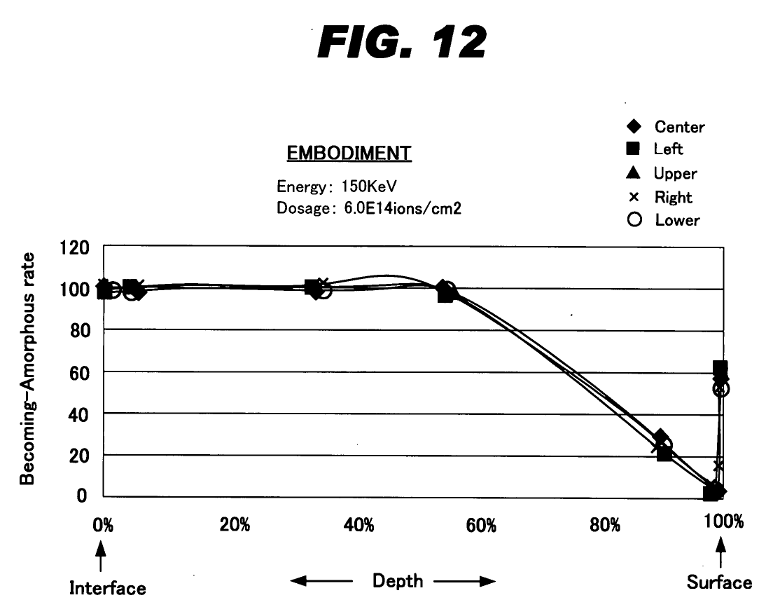

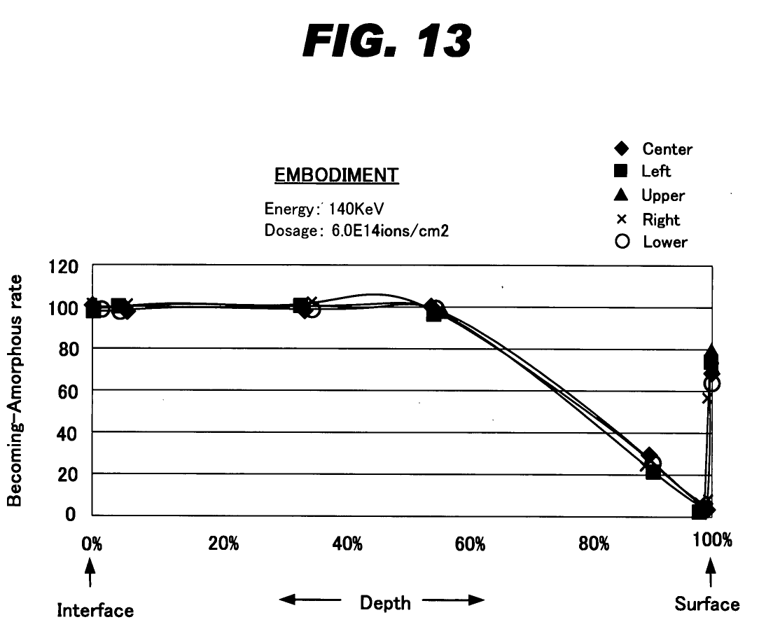

FIGS. 9 to 13 show the becoming-amorphous rate, that is, data of becoming-amorphous profile dependent upon implantation energy, of a silicon layer 12 (12b), wherein ion implantation into the silicon layer was executed under various conditions. The examples shown in FIGS. 9 and 10 employed implantation energy of 185 KeV and 170 KeV, respectively, for the conditions pertinent to comparative examples (conventional examples). The example shown in FIGS. 11, 12 and 13, to the contrary, employed implantation energy of 160 KeV, 150 KeV and 140 KeV for the condition pertinent to the present invention. It is to be noted that entire data acquisition employed the common dosage of 6.0E13 ions/cm2.

Obviously as seen from these figures, becoming-amorphous rates showed a drop in the proximity of the interface with a sapphire substrate 10 under the conventional conditions (implantation energy of 185 KeV and 170 KeV). On the other hand, employing the conditions according to this embodiment (implantation energy: 160 KeV, 150 KeV and 140 KeV) showed a success in suppressing the becoming-amorphous rate of the silicon layer at the interface with the sapphire substrate 10 from dropping. It is also to be noted that employing implantation energy of 100 KeV or less incurred the surface proximity to become amorphous.

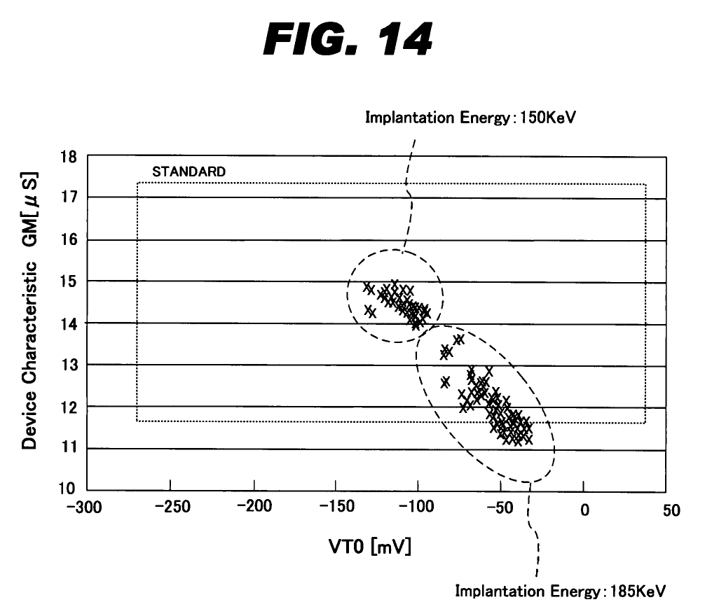

FIG. 14 is a graph showing characteristic of each semiconductor device fabricated using a wafer comprising a silicon layer subjected to ion implantation, wherein ion implantation was executed under conditions according to a comparative example (implantation energy: 185 KeV) and under conditions pertinent to an embodiment according to the present invention (implantation energy: 150 KeV). Employing the conditions of a comparative example (implantation energy: 185 KeV) suffered from deterioration of a resulted transistor characteristic (Gm). Considering the facts as shown above, it is supposed that retaining the profile of becoming-amorphous rate is essential in order to retain a good transistor characteristic.

Since defects tended to be incurred in a range of within 600 Å from the interface with the sapphire substrate in the silicon layer, more silicon ions should be implanted into this region.

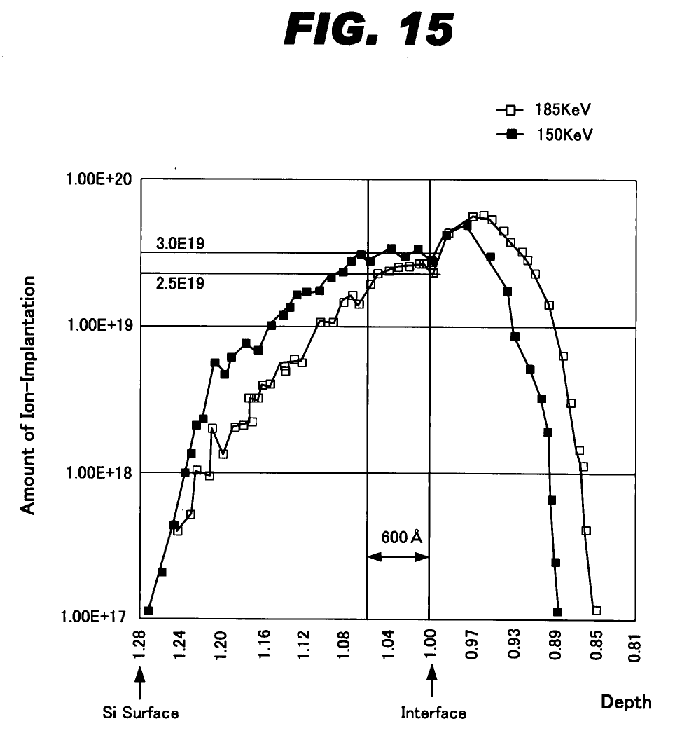

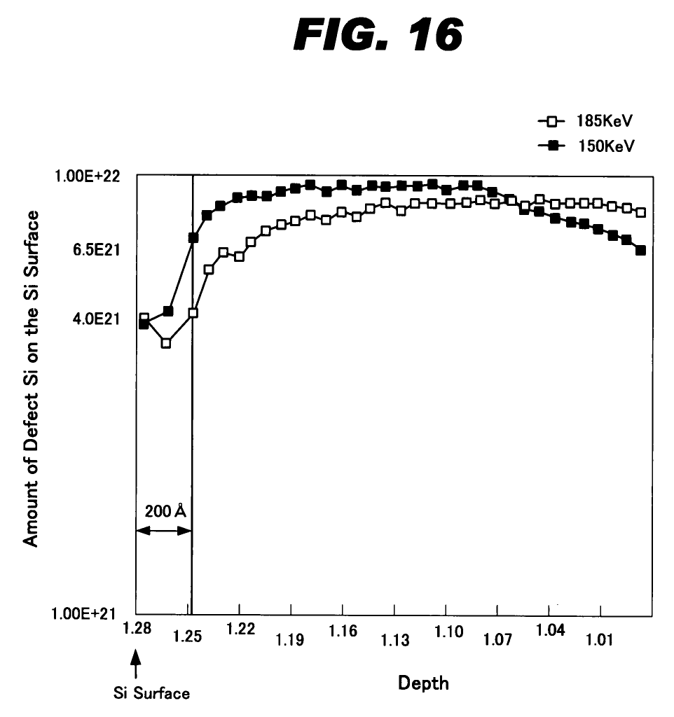

FIG. 15 is a graph showing the ion amount per unit area implanted into a silicon layer (amount of ion implantation in ions/cm3), wherein the silicon layer was subjected to ion implantation under conditions according to a comparative example (implantation energy: 185 KeV) and under conditions pertinent to this embodiment (implantation energy: 150 KeV). FIG. 16 is a graph showing the amount of defective interstitial Si existing in the proximity of the surface of a silicon layer, wherein the silicon layer was subjected to ion implantation under conventional conditions according to a comparative example (implantation energy: 185 KeV) and under conditions pertinent to this embodiment (implantation energy: 150 KeV).

Under the conditions according to a comparative example (implantation energy: 185 KeV), the amount of ion implantation per unit area in the silicon layer in the range of within 600 Å from the interface with the sapphire substrate 10 were 2.5E19/cm3. To the contrary, under the conditions according to this embodiment (implantation energy: 150 KeV), the amount of ion implantation per unit area in the silicon layer in the range of within 600 Å from the interface with the sapphire substrate 10 were 3.0E19/cm3 or more. Thus implantation of more ions into the silicon layer can reduce the defects in the silicon layer.

Increasing an amount of ion implantation, however, leads to an increase of interstitial Si existing in the surface of a silicon layer, which may incur crystallization in the surface proximity (200 Å from the surface) to be deteriorated. However, as long as the conditions according to this embodiment (implantation energy: 150 KeV) is employed as shown in FIG. 15, the transistor characteristic did not exhibit deterioration notwithstanding the increase of an amount of interstitial Si (FIG. 14). Therefore, the optimized implantation energy presented in this embodiment may be acceptable.

What is claimed is:

1. A method for fabricating a semiconductor device using a silicon on sapphire (SOS) wafer comprising the steps of:
preparing a sapphire substrate;
forming a silicon (Si) layer on said sapphire substrate;
implanting silicon ions into said silicon layer; and
epitaxially regrowthing said silicon layer after said silicon ion implantation, wherein:
said silicon ion implantation process inducing the number of interstitial Si having crystalline defects in the proximity of the surface of said silicon layer to be reduced below 6.5E2/cm3, and
said silicon ion implantation process inducing an ion implantation amount per unit area of said silicon ions in the proximity of an interface between said sapphire substrate and said silicon layer to be increased to 3.0E19 ions/cm3 or larger.

2. A semiconductor device fabricating method according to claim 1, wherein
said surface vicinity is a range of approximately 200 Å in depth from the surface of said silicon layer.

3. A semiconductor device fabricating method according to claim 1, wherein said interface vicinity is a range of approximately 600 Å from said sapphire substrate.

4. A semiconductor device fabricating method according to claim 1, wherein
said silicon ion implantation process is performed under the condition of a dosage of 8E14 ions/cm2 to 8.5E14 ions/cm2.

5. A semiconductor device fabricating method according to claim 1, wherein
said silicon ion implantation process is performed under the condition of a dosage of ion implantation energy of 140 KeV to 160 KeV.

6. A method for fabricating semiconductor devices using a Silicon-On-Sapphire (SOS) wafer comprising the steps of:
preparing a sapphire substrate;
implanting silicon ions into said silicon layer under the condition of a dosage of 8E14 ions/cm2 to 8.5E14 ions/cm2; and
epitaxially regrowthing said silicon layer after said silicon ion implantation.

7. A method for fabricating semiconductor devices using a Silicon-On-Sapphire (SOS) wafer comprising the steps of:
preparing a sapphire substrate;
forming a silicon (Si) layer on said sapphire substrate;
implanting silicon ions into said silicon layer under the condition of ion implantation energy of 140 KeV to 160 KeV; and
epitaxially regrowthing said silicon layer after said silicon ion implantation.
